(19) United States
(12) Patent Application Publication
(10) Pub. No.: US 2026/0290426 A1
(43) Pub. Date: Sep. 24, 2026

(54) 3D-DRAM WITH FOLDED DIGIT LINE QUILT LAYOUT

(71) Applicant: Micron Technology, Inc., Boise, ID (US)

(72) Inventor: Hiroki Fujisawa, Kanagawa (JP)

(73) Assignee: Micron Technology, Inc., Boise, ID (US)

(21) Appl. No.: 19/556,003

(22) Filed: Mar. 4, 2026

Related U.S. Application Data
(60) Provisional application No. 63/776,537, filed on Mar. 24, 2025.

(51) Int. Cl. G11C 11/408; G11C 11/4091

(52) U.S. Cl. CPC G11C 11/408; G11C 11/4091

(57) ABSTRACT

A 3D memory device includes multiple memory patches each of which includes a 3D array of memory cells arranged at the intersection of word lines running in a first direction, local digit lines (LDLs) running in a second direction, and global digit lines (GDLs) running in a third directions. The GDLs are organized in pairs, with each pair coupled to a sense amplifier. In an example arrangement, one GDL of the pair may be in a first metal layer while the other GDL of the pair may be in a second metal layer. The folded GDL arrangement may allow more flexibility in the placement of the sense amplifiers. For example, rather than being placed between two array sections that they are associated with, the sense amplifiers may be at the edge of a single section that they are associated with.

### CROSS REFERENCE TO RELATED APPLICATIONS

This application claims the benefit under 35 U.S.C. § 119 of the earlier filing date of U.S. Provisional Application Serial No. 63/776,537 filed Mar. 24, 2025. The aforementioned application is incorporated herein by reference, in its entirety, for any purpose.

### BACKGROUND OF THE INVENTION

Memory devices, such as DRAM devices have generally decreased in size and increased in capacity over time. Many of these gains have been accomplished by miniaturizing circuits such as the sense amplifier, sub-word line driver, and so for forth across different generations of memory devices. However, it is difficult to decrease the size of components below certain size thresholds, which makes it difficult to continue to improve memory device capacity and size in this manner.

It may be possible to increase memory device size and capacity by arranging memory cells in a three dimensional grid instead of a two-dimensional array. For example, multiple memory chips may be stacked on top of each other. However, this increases the thickness of the overall memory device to an extent that may be difficult to accommodate and the number of stacked chips is limited by concerns such as the length of signal lines through the stack, alignment of timing signals, and so forth. Other technologies may be used to generate 3D arrays of memory cells, such as the 3D arrays found in flash memory, but these may have limitations in the speed at which the memory device operates and are generally much slower than the speeds required of a DRAM device. There may be a need for 3D memory devices which operate at high speeds.

### BRIEF DESCRIPTION OF DRAWINGS

FIG. 1 is a block diagram of a 3D memory device according to some embodiments of the present disclosure.

FIG. 2 is a perspective drawing of a memory device with an inset showing a ‘top down’ view of an example memory quilt according to some example embodiments of the present disclosure.

FIG. 3 is a perspective schematic diagram of a portion of a 3D memory array according to some embodiments of the present disclosure.

FIG. 4 is a perspective view of a memory quilt of a memory device according to some embodiments of the present disclosure.

FIG. 5 is a top-down view of a memory quilt according to some embodiments of the present disclosure.

FIG. 6 is a cross sectional view of a memory device according to some embodiments of the present disclosure.

FIG. 7 is a cross sectional view of a memory device according to some embodiments of the present disclosure.

FIG. 8 is a cross sectional view of a memory device according to some embodiments of the present disclosure.

FIG. 9 is a flow chart of a method of operating a 3D memory device according to some embodiments of the present disclosure.

### DETAILED DESCRIPTION OF THE INVENTION

The following description of certain embodiments is merely exemplary in nature and is in no way intended to limit the scope of the disclosure or its applications or uses. In the following detailed description of embodiments of the present apparatuses, systems, methods, and combinations thereof, reference is made to the accompanying drawings. The drawings are shown by way of illustration of specific example embodiments of how the described apparatuses, systems, methods, or combinations thereof may be practiced. These embodiments are described in sufficient detail to enable those skilled in the art to practice presently disclosed apparatuses, systems, methods, and combinations thereof, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

A memory device includes a memory array. The memory array includes a number of memory cells which store information. For example each memory cell may store a single bit of information as a charge on a capacitive element. In a conventional 2D memory device, the memory cells are logically organized at the intersection of rows and columns. Conductive elements known as word lines couple memory cells along a row, and conductive elements known as digit lines or bit lines couple memory cells along a column. Accordingly, a row address may be used to specify a word line and a column address may be used to specify one or more of the digit lines.

The memory array may be formed of repeating units, referred to as ‘sections’. These sections include one or more patches of the memory array and various circuits which support the operation of that patch. For example, a section may include the patch, sense amplifiers (SA) coupled to the digit lines of that patch, and sub-word line drivers (SWD) coupled to the word lines of the patch. For example, in a conventional 2D memory device, the memory array patch may be generally rectangular with SAs positioned along a ‘top’ and ‘bottom’ edge of the patch and SWDs positioned along a ‘left’ and ‘right’ edge. The top row of sense amplifiers are coupled to either even or odd digit lines (in this and in an adjacent patch), the bottom row of sense amplifiers are coupled to the other digit lines (in this and in an adjacent patch). The SWDs along the edges are similarly coupled to alternate word lines in the patch.

While this layout may be efficient for 2D memory devices, when a third dimension is added, it may become more complicated to generate sections which are compact and which repeat across the memory device. For example, the need for connections to run in a third axis may complicate the placement of components such as SAs and SWDs compared to 2D memory. In addition the expansion into a third dimension may increase the memory cell density enough that it is possible to relax the pitch, or spacing, between components, which may allow more flexible layouts to be used compared to the layouts which are possible with the stringent pitch requirements of 2D memory. For example, a 3D memory device may have generally greater spacing between components such as word lines, sense amplifiers, and sub-word line drivers compared to a 2D memory. There may be a need for new layouts in 3D-DRAM devices to take advantage of the flexibility that 3D affords.

The present disclosure is drawn to apparatuses, systems, and methods for 3D-DRAM with an folded digit line quilt layout. An example 3D-DRAM device includes memory cells arranged at the intersection of word lines and local digit lines with the local digit lines coupled together by global digit lines. The word lines, local digit lines, and global digit lines may generally extend in directions which are mutually orthogonal to each other. The present application uses the convention that the word lines generally extend along an ‘x’ direction, the local digit lines generally extend along a ‘z’ direction, and the global digit lines generally extend along a ‘y’ direction. The x, y, and z directions may be orthogonal to each other.

The present disclosure relates to a layout for the sections referred to as a ‘quilt’ which includes a folded digit line architecture. The quilt includes a first memory patch and a second memory patch. Word line extend from the first patch to the second patch through a staircase region. Sub-word line drivers are positioned above the staircase region and couple to respective ones of the word lines through the staircase region. A first sense amplifier region is positioned above the first memory patch and a second sense amplifier region is positioned above the second memory patch. Each sense amplifier region includes sense amplifiers each coupled to a pair of global digit lines in the associated memory patch. The local digit lines along the length of the global digit line pair (e.g., along the y direction) are coupled to one or the other of the global digit lines of the pair of global digit lines. During operations, one of the pair of coupled global digit lines is used to carry a signal and the other is used as a reference. This may be referred to as a folded digit line architecture, since both coupled global digit lines extend away from the sense amplifier in a same direction (e.g., both extend in the +y or both extend in the -y direction) rather than in opposite directions as in a conventional device. The use of a folded digit line architecture may allow for more flexible placement of the sense amplifiers within the quilt, which in turn may allow for a more compact arrangement of the memory quilt. This in turn may allow for more compact memory devices, more capacity on a memory device, or combinations thereof. For example, the sense amplifiers may be positioned over an edge of associated memory patch rather than between two associated memory patches.

In some embodiments, the pair of global digit lines coupled to the same sense amplifier may be stacked on top of each other in the z direction. For example a first global digit line of the pair may be in a first metal layer and the second global digit line of the pair may be in a second metal layer stacked above the first metal layer. In some embodiments, the global digit lines of a pair may ‘twist’ or change which global digit line is on top and which is on bottom. The lower global digit line is coupled to local digit lines while the upper is not. The twisting may allow changes between which of the pair of global digit lines the local digit lines are coupling to. In this way along the length of the GDL pair there are portions where one GDL is on top and the other on the bottom and portions where that is reversed.

In some embodiments, the memory quilt may also include multiplexers which selectively couple the local digit lines to the global digit lines. Sets of multiplexers are coupled in common to a multiplexer driver. The multiplexer drivers are positioned in multiplexer driver regions which are also positioned above the memory patches.

In some aspects, the present application relates to the spatial arrangement of various components. As used herein, when a circuit element is referred to as extending in or along a direction or axis, it refers to a component that is primarily extended in that dimension. However, such an element need not be a perfect line and may have portions which do not exclusively run in the given direction. For example, while a word line may primarily extend along the x axis, it may have portions which briefly extend in the y and/or z directions. As used herein, when a component is referred to as being ‘above’ or ‘below’ another component, it means that at least a portion of the footprint of that component overlaps at least a portion of the footprint of the other component when projected on at least one plane but that they are offset in at least one axis. For example, in some embodiments the sense amplifier region may be above the array patch in the z direction. At least a portion of the xy footprint of the sense amplifier region overlaps at least a portion of the xy footprint of the array patch region, however the sense amplifier region occupies a different range of space long the z coordinate than the array patch region.

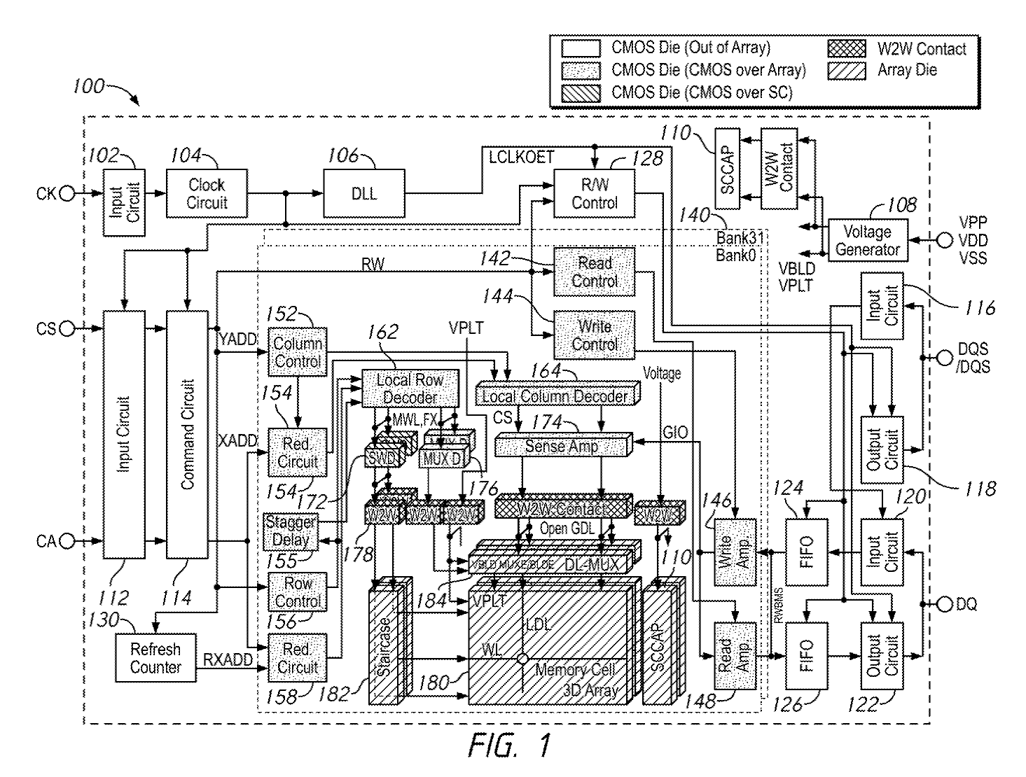

FIG. 1 is a block diagram of a 3D memory device according to some embodiments of the present disclosure. The view of the 3D memory device 100 in FIG. 1 is a block diagram representing the different components of the 3D memory device 100. It does not represent the spatial layout of the components of the device, except where otherwise noted.

The 3D memory device 100 may be coupled to a controller (not shown in FIG. 1) which provides various commands, data, and other signals to the memory device 100 to operate the memory. In some embodiments, the 3D memory device 100 may be a stand-alone device. In some embodiments the 3D memory device 100 may be part of a module that packages together several similar memory devices.

The 3D memory device 100 includes a number of external terminals which receive various signals which are used by the device 100. The signals which are received, as well as the signals within the memory device 100, are generally represented by voltages, which different levels of voltage representing different states of the signal. For example, many of the signals used by the memory device 100 may be binary signals, where a first voltage level represents a logical high and a second voltage level represents a logical low. Example terminals include a clock terminal CK, a chip select terminal CS, a command/address terminal CA, data strobe terminals DQS and /DQS, data terminals DQ, and voltage terminals such as VPP, VDD, and VSS. Any of those example terminals may include one or more individual terminals.

The clock signal CK is received by the clock terminal and provided through an input circuit 102 to a clock circuit 104. The clock signal CK is used to control the timing of operations in the memory device 100. The clock circuit 104 generates one or more internal clock signals based on the external clock signal CK and distributes them to various other components of the memory device 100. The clock circuit 104 also provides the clock signal to a delay locked loop (DLL) circuit 106 which generates a delayed clock signal LCLKOET. The delayed clock circuit may be used to match a timing it takes the clock signal to propagate through the memory device 100 and may be used to time read operations. The 3D memory device 100 also receives and provides data strobes DQS and /DQS through a respective input circuit 116 and output circuit 118. During write operations the memory receives a data strobe signal used to time operations of the input circuit 120 for the data DQ. During read operations the memory 100 provides the delayed clock signal LCLKOET to time the operations of a data output circuit 122 to the data terminal DQ. Buffer circuits 124 and 126 are used to serialize or deserialize data between the memory device and the DQ terminals.

The memory device 100 receives voltages at voltage terminals. The voltages are provided to a voltage generator circuit 108 which generates one or more internal voltages based on the provided voltages. The provided voltages as well as the generated voltages are distributed to the various circuits of the memory device 100. For example, the memory device 100 may receive a ground voltage VSS and a system voltage VDD as well as a voltage VPP. The memory includes SC capacitors 110 which help regulate voltages in the memory array 180. The SC capacitors or SCCAPs 110 are located in the memory array 180 and are coupled to the voltage generator circuits 108 through wafer contacts in some embodiments.

The memory receives commands and addresses along a command/address bus coupled to CA terminals. The 3D memory device 100 also receives a chip select signal CS, which is used to time signals along the CA terminals, as well as indicate which memory device 100 is receiving commands and addresses in embodiments where multiple memory devices are packaged together. The CS and CA signals are passed through an input circuit 112 to a command/address circuit 114. Examples of addresses include bank address BADD which specifies a bank of the memory device 100, row address XADD which specifies a row of the device, and column address YADD which specifies a column of the device. Examples of commands include activation commands ACT, pre-charge commands PRE, access commands such as read R or write W, or refresh commands. Certain commands and addresses may generally be received together. For example the CA terminal may receive a row activation command ACT along with a row address XADD and bank address BADD. Access commands such as read or write may generally be received along with a column address YADD. A read/write control circuit 128 helps manage the RW commands.

The 3D memory device 100 is divided into one or more memory banks 180. In the embodiment of FIG. 1, there are 32 banks, labelled Bank0 to Bank31. More or fewer banks may be used in other example embodiments. Each bank is associated with a bank logic region 140, which includes the memory array 180 of the bank as well as various circuits associated with that bank. These circuits may generally be repeated on a bank-by-bank basis. An example bank logic region 140 may include a column control circuit 152 and column redundancy circuit 154, a row control circuit 156 and row redundancy circuit 158, local row decoder 162, local column decoder 164, sub-word line drivers 172, sense amplifiers 174, multiplexer drivers 176, the array 180 and staircase region 182, digit line multiplexers 184, write amplifiers 146 and read amplifiers 148.

The array 180 is a 3D array with memory cells coupled at the intersection of word lines WL and local digit lines LDL. The view of FIG. 1 shows an example slice of the array through an xz plane, showing an example WL and LDL. The LDLs are coupled together along a y axis by pairs of global digit lines GDL. The pair of GDLs coupled to a same sense amplifier of the sense amplifiers 174. Along the length of the GDL pair, a portion (e.g., a first half) of the LDLs are coupled to one GDL in the pair, and a portion (e.g., a second half) of the LDLs are couple to the other GDL in the pair. In some embodiments, multiplexers 184 are used to select which of the intersecting LDL(s) are coupled to the respective GDL, and through that GDL to the sense amplifier. The local row decoder 162 is used to selectively activate multiplexer drivers 176 based on the row address, which activates respective ones of the multiplexers 184. In some embodiments, the multiplexers 184 and their respective drivers 176 may not be used and may be eliminated.

The row control circuit 156 activates a word line of the memory array 180 based on the row address. The row control circuit 156 provides internal signals to the local row decoder circuits 162. The local row decoder circuit 162 activates a sub-word line driver 172 associated with the word line specified by XADD. The sub-word line driver 172 is coupled to an associated word line WL through the staircase 182. The sub-word line driver selected by the row address activates the associated word line, causing the memory cells along that word line to couple to the intersecting local digit lines LDLs. The LDLs are coupled to one of each of the intersecting pairs of GDLs. The sense amplifier compares the signal along the GDL of the pair coupled to the active word line (through the LDL) to a reference along the GDL of the pair which is not coupled to the active word line. In some embodiments, the local row decoder circuit 162 also activates a multiplexer driver 176 which in turn selects multiplexers 184 to couple the LDLs which intersect the selected word line to the GDLs.

The multiplexers 184 may be an optional component used in some example embodiments. In embodiments where multiplexers are used, the local row decoder circuit 162 receives the row address XADD and uses the row address to determine which multiplexer(s) 176 to activate. Based on the row address the local row decoder circuit 162 provides decoded address to the multiplexer drivers 176, and the multiplexer driver(s) associated with the decoded address provide a multiplexer driver signal. The multiplexers 176 may be grouped together in sets, and the sets are coupled in common to a multiplexer driver 176 provides the multiplexer driver signal, the multiplexers in the set are activated and couple the associated LDL to the respective GDL of the GDL pair. In some embodiments, when the multiplexer driver signal is inactive, the LDL may be decoupled from the GDL and coupled to a ground voltage instead.

A stagger delay circuit 155 controls a timing of the operation of the local row decoder circuit 162. For example, the stagger delay circuit 155 may use internal signals to control when the local row decoder circuit 162 activates the SWD 172 and when it activates the multiplexer driver 176.

The column control circuit 152 selects which global digit lines to couple to global input/output lines GIO based on the column address YADD. During a write operation, the GIO lines are coupled to a write amplifier 146, which provides data received from the input circuit 120 through the GIO lines to the selected GDL lines and through those to the memory cells at the intersection of the selected WL and LDL. During a read operation, the data from the memory cells at the intersection of the selected WL and LDL are coupled through the selected GDL to the read amplifier 148, which provides the read data to the output circuit 122.

The memory bank logic region 140 also includes redundancy circuits 154 and 158. The redundancy circuits 154 and 158 are used as part of repair operations. If a row or column address has been repaired, the redundancy circuits 154 or 158 will direct access to a redundant word line or redundant column.

In an example write operation, data received along the DQ terminals is written to specified memory cells of the 3D memory device 100. The device 100 receives a row activation command along with a row address. The local row decoder 162 selects SWDs 172 to activate the associated word line based on the row address and may activate a multiplexer driver 176. The device 100 receives a write command along with a column address. Data is received by the input circuit 120 and deserialized by a buffer circuit 124 which provides the data to write amplifiers 146. The local column decoder 164 couples selected global digit lines to the GIO lines based on the column address YADD. In some embodiments, a multiplexer driver 176 is activated by the local row decoder 166 and couples a local digit line which intersects the active word line to the respective global digit lines. The data from the write amplifier 146 is written along the GIO lines to GDL line, onto the selected LDL lines and into the memory cells at the intersection of the LDL with the active word line WL.

In an example read operation, data from the array 180 is provided out along the DQ terminals. The device 100 receives a row activation command along with a row address. The local row decoder 162 selects SWDs 172 to activate the associated word line based on the row address. In some embodiments, the global row decoder 166 selects a multiplexer driver 176 to selectively couple one or more selected LDLs to the respective GDL. Data is read out from the memory cells which intersect the active word line through the intersecting LDLs and along the GDLs. The device 100 receives a read command along with a column address. Data is read out from selected ones of the GDLs along the GIO lines to a read amplifier 148. The read amplifier provides the read data to a buffer 126 which serializes the data and provides the serialized data to the output circuit 122.

The 3D memory device 100 may also perform refresh operations. As part of a refresh operation, one or more word lines have the data in the intersecting memory cells refreshed. For example, the memory cells may store information as charge on a capacitive element, and that charge may decay over time. A refresh operation restores that charge to a nominal value. Responsive to a refresh command, a refresh control circuit 130 provides one or more refresh addresses RXADD which specify which word line or word lines should be refreshed.

FIG. 1 generally shows the 3D memory device 100 as a flattened 2D drawing. However certain components may be positioned over other components in an example implementation. For example, the bank logic circuits 140 may be positioned ‘above’ (in the z direction) the memory banks 180. For example, the sub-word line drivers 172 may be positioned above the staircase 182. In some embodiments, the memory device 100 may be printed on two chips, which are then bonded together. For example, components such as the array 180, staircase 182 and digit line multiplexers 184 may be printed in an array die, while the other components are printed on a CMOS die. A set of wafer to wafer (W2W) contacts 178 couple the CMOS die to the array die. In some embodiments, certain components may be positioned above the memory array. For example, at least some of the sense amplifiers 174 may be positioned above the array 180.

The present disclosure will generally be described with respect to an example implementation where two chips are used, however other implementations using more or fewer chips may also be used, and other arrangements of components between chips may be used.

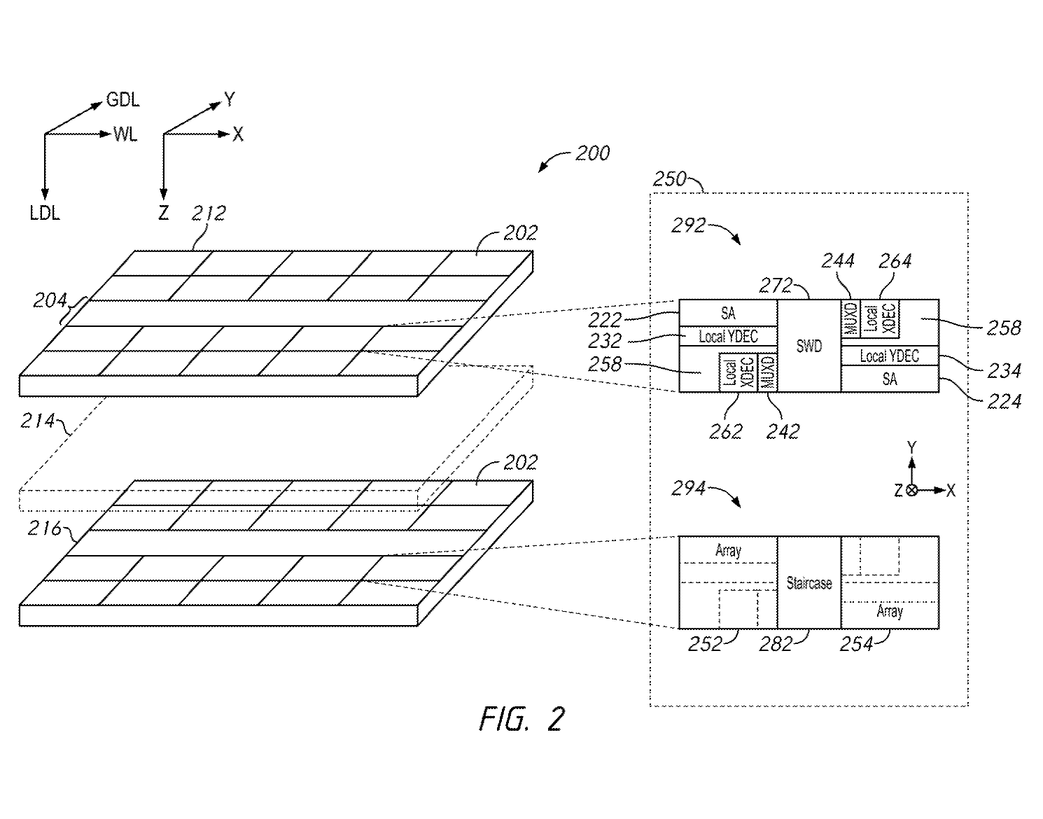

FIG. 2 is a perspective drawing of a memory device with an inset showing a ‘top down’ view of an example memory quilt according to some example embodiments of the present disclosure. The memory device 200 may, in some embodiments, represent a layout which implements the 3D memory device 100 of FIG. 1.

The memory device 200 includes a number of memory quilts 202, each of which includes one or more portions of memory array, such as memory patches, as well as circuitry which supports the operation of those patches such as SAs (e.g., 174 of FIG. 1) and SWDs (e.g., 172 of FIG. 1). The memory quilts 202 are tiled in the x-y plane of the memory die 200. The memory quilts 202 are sections of the memory array. They may be referred to as quilts herein, because when considered in the xy plane the repeating patterns of circuits tiled across surface of the device are evocative of quilt patches. The memory device 200 also includes a peripheral region 204, which does not have memory quilts 202 tiled across it. The peripheral region 204 may include other circuits which are used in the operation of the memory such as the command circuit 114 of FIG. 1, the input and output circuits 116-122 of FIG. 1 and other components.

The memory device 200 is formed from two die, a first die 212 and a second die 216. The first die 212 is stacked on top of the second die 216 in the z-direction. The first die 212 may be a die which includes various circuits and components which operate the memory device 200, while the second die 216 may be an array die which includes the memory cells, word lines, local digit lines and global digit lines. The second die 216 may also include components which are used to couple components together such as the staircase. The first die 212 may generally be referred to as a CMOS die and the second die 216 may generally be referred to as an array die.

The two die 212 and 216 may be bonded together. For example, wafer-to-wafer (W2W) bonding may be used. A bottom surface in the z direction of the first die 212 may have one or more connection points such as bumps. A top surface in the z direction of the second die 216 may have corresponding connection points such as bumps. When the two die are bonded, the connection points may be electrically coupled between corresponding bumps. In some embodiments, an optional bonding layer 214 between the two die may be used.

In the example of FIG. 2, the peripheral region 204 extends across a width of the two die 212 and 216 in an x-direction, and a portion of the surface of the dice 212 and 216 in the y-direction. The peripheral region 204 is generally centered in the device along the y-axis. The device 200 has memory sections 202 positioned in a grid layout above in the +y direction and below in the -y direction the edges of the peripheral region 204. Other arrangements of the peripheral region 204 and quilts 202 may be used in other example embodiments. FIG. 2 shows a simplified view with a 2x5 grid of quilts 202 on either side of the peripheral region 204. However, more or fewer quilts 202, or different arrangements of quilts 202 may generally be used in other example embodiments. For example, an implementation of a memory device may generally be expected to include many more quilts 202 than the twenty sections illustrated in FIG. 2.

Both die 212 and 216 have memory quilts 202 which have respective portions tiled across the surface of the two die. Each memory quilt 202 has a portion 292 on the first die 212 and a portion 294 on the second die 216. The portions 292/294 of a given memory quilt 202 across the two die are vertically stacked so they align in an x-y plane and are stacked in the z direction.

The inset 250 shows a ‘top down’ view in the xy plane of a quilt 202. The quilt 202 includes two memory patches 252 and 254. Each memory patch 252 and 254 includes a 3D array of memory cells at the intersection of word lines and local digit lines, with the local digit lines coupled together by global digit lines. As well as the memory patches 252 and 254, the quilt 202 also includes sense amplifier portions 222 and 224, local column decoder 232 and 234, multiplexer driver regions 242 and 244, local row decoders 262 and 264, sub-word line driver region 272, and staircase region 282. The sense amplifier portions 222 and 224, local column decoder 232 and 234, multiplexer driver regions 242 and 244, local row decoders 262 and 264, and sub-word line driver region 272 are located in the portion 292 on the first die 212. The array patches 252 and 254 and the staircase region 282 are located in the second portion 294 in the second die 216.

The portion 292 of the quilt 202 in the first die 212 also includes spacer regions 258, located on either side of the SWD region 272. These spacer regions 258 are located above the memory array patches 252-257 in the z direction. The spacer regions 258 may be regions of the first die 212 which are generally empty of circuits in some embodiments.

The example layout of the quilt 202 shown in the inset 250 may be used for each of the quilts 202. The patches 252 and 254 may be generally thought of as rectangular prisms, with a ‘top’ of the prism in the xy plane shown in the inset 250. Each patch 252 and 254 is also elongated along the z-axis, which is not shown in the ‘top down’ view of FIG. 2A. The two patches 252 and 254 may have generally the same dimensions as each other. The staircase region 282 is positioned between the two array patches 252 and 254 such that the staircase region 282 separates the two patches 252 and 254 along the x axis. Like the memory patches, the staircase region 282 may be thought of as a rectangular prism elongated in the x, y and z directions. The staircase may have generally the same height in the y axis as the two adjacent memory patches 252 and 254.

The SWD region 272 is positioned above the staircase region 282. The SWD region 272 may generally have the same x and y dimensions as the staircase region 282. Each spacer region 258 is positioned above a corresponding one of the array patches 252 and 254. Each of the patches 252 and 254 has an associated sense amplifier region, local column decoder, multiplexer driver region, and local row decoder. For example, the array patch 252 is associated with sense amplifier region 222, local column decoder 232, multiplexer driver 242 and local row decoder 262, while the array patch 254 is associated with sense amplifier region 224, local column decoder 234, multiplexer driver 244 and local row decoder 264.

The sense amplifiers are positioned above the patches 252 and 254 they are associated with. For example, the sense amplifier region 222 is above the patch 252 and the region 224 is above the patch 254. Each of the sense amplifiers in the region is coupled to the respective global digit lines via vertical conductive elements run in the z direction down from the first die 212 to the second die 216. Each sense amplifier may be coupled to a pair of global digit lines in the respective memory patch. In some embodiments, each sense amplifier region 222/224 includes sense amplifiers arranged in a grid in the xy plane.

The sense amplifier regions 222 and 224 may be above a portion of the associated memory patch 252 and 254. For example, the sense amplifier regions may generally have a same width in the x direction as the memory patches 252/254, but a shorter height in the y direction. The two sense amplifier regions 222 and 224 may be aligned with opposite edges of the memory patches. For example, an upper (in the y direction) edge of the sense amplifier region 222 is aligned with an upper edge of the memory patch 252, while a lower edge of the sense amplifier region 224 is aligned with a lower edge of the memory patch 254.

Each sense amplifier region 222 and 224 is associated with a respective local column decoder 232 and 234 (e.g., 164 of FIG. 1). During operations, the local column decoders 232/234 use the column address to determine which global digit lines are coupled outside of the array along the global input/output (GIO) lines. The local column decoders 232/234 are positioned over the array, next to the associated sense amplifier region. For example, the local column decoders 232/234 may be along an ‘interior’ edge of the associated sense amplifier region. For example, the sense amplifier region 222 has an upper edge aligned with an upper edge of the patch 252, and the associated local column decoder 232 along its lower edge.

The multiplexer drivers are positioned above the patches 252 and 254 they are associated with. For example, the multiplexer driver region 242 is above patch 252 and the multiplexer driver region 244 is above the patch 254. An edge of the multiplexer driver regions 242/244 is aligned with an edge of the SWD region 272. For example, a right (in the x direction) edge of the multiplexer driver region 242 borders a left edge of the SWD region 272, and a left edge of the multiplexer driver region 244 borders a right edge of the SWD region 272. Each of the multiplexer driver regions has an associated local row decoder 262/264 (e.g., 162 of FIG. 1) which is along an edge of the multiplexer driver region 242/244 opposite the edge which borders the SWD region. For example, the multiplexer driver region 242 borders the SWD region 272 along itsright edge and the associated local row decoder 262 along its left edge. The multiplexer driver regions 262/264 are opposite the sense amplifier regions 222/224. For example, an upper edge of the sense amplifier region 222 is aligned with an upper edge of the patch 252, and a lower edge of the multiplexer driver region 242 is aligned with a lower edge of the patch 252.

The memory array patches 252 and 254 represent a piece of the 3D array. For example, each memory patch 252-257 includes memory cells positioned at the intersection of word lines extending along the x axis and local digit lines extending in the z direction, which is into the plane of the page in the view of the inset 250. The local digit lines are coupled together in columns running in the y direction by global digit lines.

The word lines extend between two of the patches 252 and 254. For example, a word line may be continuous across the width of the array patch 252, through the staircase region 282 and across the width of the array patch 254. The word lines intersect memory cells in the array patches, but not in the staircase region when passing through the staircase region 282. For example, a word line intersects local digit lines and memory cells in the array patch 252, then passes through the staircase region 282 without intersecting memory cells or LDLs, and then intersects LDLs and memory cells again in the array patch 254. In other words, when considered along its length in the x direction, each word line has a gap where there are no coupled memory cells in the staircase region.

The SWD regions 272 and 276 include a number of SWDs, each of which is coupled to a respective word line which extends across both of the associated array sections 252/254 through the staircase region 282. For example, a first SWD in the region 272 is coupled to a first word line which extends across both array patches 252 and 254, a second SWD in the region 272 is coupled to a second word line which extends across both array patches 252 and 254, and so forth. The SWDs in the SWD region 272 are arranged in a grid, which has dimensions based on the number and arrangement of word lines in the adjacent memory patches 252/254. For example, if there are M word lines in the y-direction and N word lines in the z direction across the two patches 252/254 for a total of NxM word lines in the two patches, then there will also be NxM SWDs in the region 272. For example, the region 272 may have a grid of SWDs with M SWDs in the y-direction and N SWDs in the x direction. Along a given row in the x direction, each SWD couples to a different depth of word line in the z-direction using a connective element which extends along the z-direction to the associated word line.

The global digit lines in the array patches 252 and 254 are coupled to sense amplifiers in the associated sense amplifier portions 222 and 224. The global digit lines in the patch 252 are coupled to sense amplifiers in the region 222 and the global digit lines in the patch 254 are coupled to sense amplifiers in the region 224. Each sense amplifier is coupled to two global digit lines, both in the same patch. For example, each sense amplifier may be coupled to a pair of global digit lines which are adjacent to each other. In some embodiments, the pair of global digit lines may be stacked on top of each other in the z direction. For example they may run in different metal layers. This layout may be referred to as a folded architecture, since the two digit lines run in a same direction (e.g., both run in the +y direction or in the -y direction) away from the sense amplifier. One of the pair of global digit lines is referred to as a ‘true’ global digit line or GDLT and the other is referred to as a ‘bar’ global digit line GDLB. Along the pair of GDLs, some local digit lines are coupled to GDLT and some are coupled to GDLB. During operations, one of the GDLT and GDLB is used to carry a signal to or from a memory cell and one is used as a reference by the coupled sense amplifier, depending on which word line is activated.

In some embodiments, the sense amplifiers within a region may be arranged in a grid. For example, if there are L global digit line pairs, there may be L sense amplifiers. The sense amplifiers may be arranged in a grid of I x J sense amplifiers, where I*J = L. The arrangement of the grid may be based, in part, on the size of the sense amplifiers in the x direction relative to the spacing of the GDL pairs in the x direction. For example, if a sense amplifier is generally as wide as four GDL pairs, then the sense amplifiers may be arranged in a grid with columns of four sense amplifiers each, with each of sense amplifier coupled to a different one of the GDL pairs than runs below that column.

In an example implementation, each of the memory patches 252 and 254 may include about 8Mbit of storage or about 8,192,000 memory cells. An example memory patch 252 has 8000 word lines arranged in a grid in the yz plane of 80 word lines in the y direction and 100 word lines in the z direction. The word lines are intersected by a grid in the xy plane of 1024x80 local digit lines with 1024 local digit lines in the x direction and 80 in the y direction. Each ‘column’ of 80 local digit lines is coupled to one or the other of a pair of associated global digit lines for a total of 1024 global digit line pairs or 2048 total global digit lines. The associated sense amplifier region 222 includes 1024 sense amplifiers, each coupled to a pair of global digit lines. The sense amplifiers may be arranged in an xy grid of 256 sense amplifiers in the x direction and 4 sense amplifiers in the y direction. Each sense amplifier is coupled to the associated GDL pair by a vertical (in the z direction) element running down to the GDL running below the sense amplifier. The SWD region 272 includes 8000 SWDs, one for each word line, arranged in a grid in the xy plane of 80 SWDs in the y direction and 100 in the x direction. The multiplexer driver region 242 includes half of the total multiplexer drivers, arranged in a column in the y direction. For example, if each multiplexer driver is coupled to a single LDL, then there are 80 total multiplexer drivers, 20 of which are in the region 242 (the other 20 are in region 244).

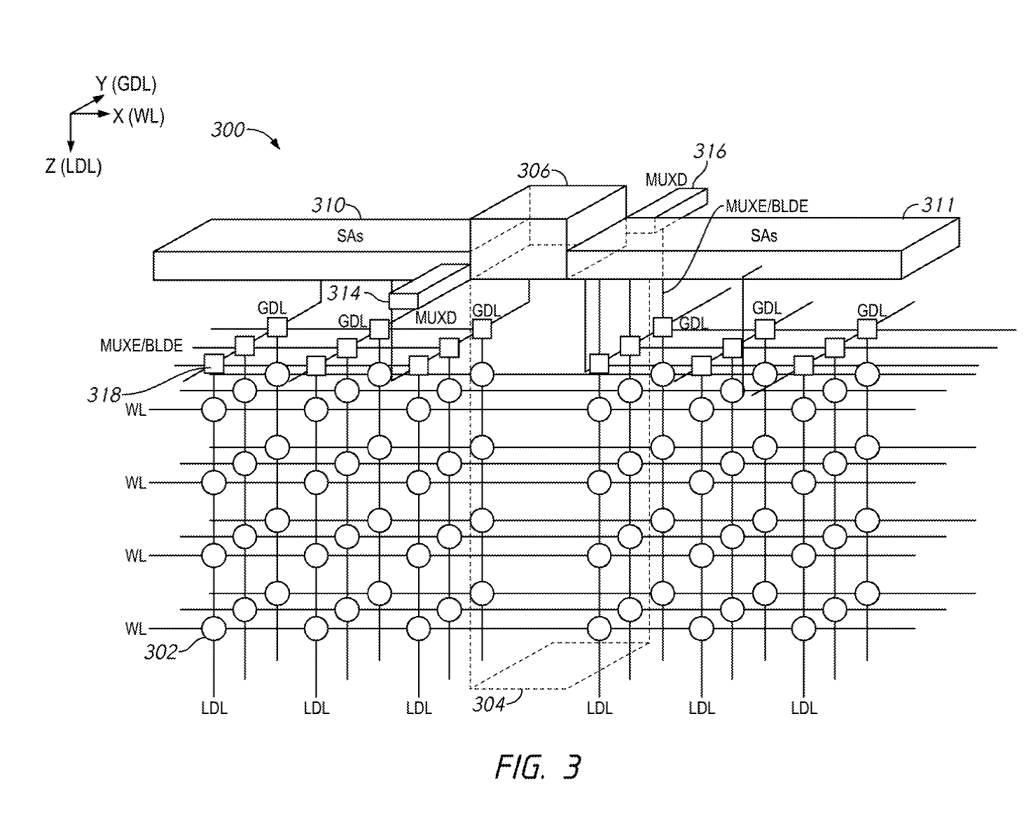

FIG. 3 is a perspective schematic diagram of a portion of a 3D memory array according to some embodiments of the present disclosure. The 3D memory array 300 represents a simplified view of an example portion of a memory array. For example, the 3D memory array 300 may represent a portion of the 3D array 180 of FIG. 1, and/or a representation of the quilt 202 of FIG. 2. The perspective of FIG. 3 shows an example set of memory cells 302 and their respective word lines, local digit lines and paired global digit lines. The view of FIG. 3 may be a simplified representational view which shows a relatively small number of word lines, global digit lines, local digit lines etc.

The memory array 300 shows memory cells 302. Each memory cell 302 is positioned at the intersection of a word line WL and a local digit line LDL. Each LDL is associated with one or the other of a pair of GDLs. The paired global digit lines are both coupled to a respective sense amplifier in the sense amplifier portions 310-311 (e.g., 174 of FIG. 1 and/or 222-224 of FIG. 2). The word lines are each coupled to a respective SWD in a SWD region 306 (e.g., 172 of FIG. 1 and/or 272 of FIG. 2). The word lines are coupled via a staircase region 304 (e.g., 182 of FIG. 1, 282 of FIG. 2) to the SWD region 306. Also shown are multiplexer driver regions 314 and 316 (e.g., 176 of FIG. 1 and/or 242-248 of FIG. 2) which couple to multiplexer circuits 318 (e.g., 184 of FIG. 1).

In some embodiments the SA regions 310-311, multiplexer drivers 314-316 and SWD region 306 may be in a different die than the die which includes the WL, LDL, GDL, memory cells 302 and multiplexer circuits 318. The view of FIG. 3 shows an example embodiment similar to the embodiment of FIG. 2, where the sense amplifier regions 310-311 are positioned above the array patches. In particular, the view of FIG. 3 may represent the patches 252 and 254 of FIG. 2, as well as their associated staircase region 282, sense amplifier regions 222 and 224, SWD regions 272, and multiplexer driver regions 242 and 246. The local column and row decoders are omitted from the view of FIG. 3.

The staircase region 304 is a 3D region, which may be generally have the form of a rectangular prism. The staircase region 304 is positioned underneath the SWD region 306 in the z-direction. In some embodiments, the staircase region 304 may have the same x-y dimensions as the SWD region 306. The staircase region 304 is positioned between two sections of the word lines WL which intersect memory cells 302. However, the WLs may not intersect any memory cells while they pass through the staircase region 304. Vertical connection elements which extend in the z direction (not shown in FIG. 3) couple each word line to a respective SWD in the SWD region 306. A middle of the word lines WL may be positioned in the staircase region 304.

The word lines WL are arranged in a grid when considered in the yz plane. Similarly, the LDLs may be arranged in a grid when considered in the xy plane. The GDLs are generally arranged in a plane side-by-side with each other.

The LDLs are selectively coupled to one of the GDLs of the associated pair of GDLs through a multiplexer circuit 318. Some of the LDLs along the length of the GDL pair are coupled to one of the GDLs in the pair and some of the LDLs are coupled to the other. For example, each GDL in the pair of GDLs may be coupled to roughly half of the LDLs along the length of the GDL pair. The multiplexers are coupled to multiplexer drivers in a multiplexer driver region 314 or 316. A line of multiplexer drivers may be coupled in common by a multiplexer driver line along the x direction to a multiplexer driver in the multiplexer driver region 314/316. The multiplexer driver provides a multiplexer enable signal MUXE. When MUXE is active, all the multiplexers 318 which are coupled in common to that signal line will couple their respective LDL to the associated GDL.

In some embodiments, the multiplexer drivers 314/316 may also provide a bleed enable signal BLDE. When the bleed enable signal BLDE is active, the multiplexer couples the respective LDL to a ground voltage. In an example operation, the multiplexer driver associated with the row address provides an active MUXE signal and an inactive BLDE signal while the multiplexer drivers which are not associated with the row address provide an active BLDE signal and an inactive MUXE signal. Accordingly, during the operation, multiplexers which receive an active MUXE couple their LDLs to the GDL, while the other multiplexers along each GDL isolate their LDLs from the GDL and instead couple them to a ground voltage so they do not float.

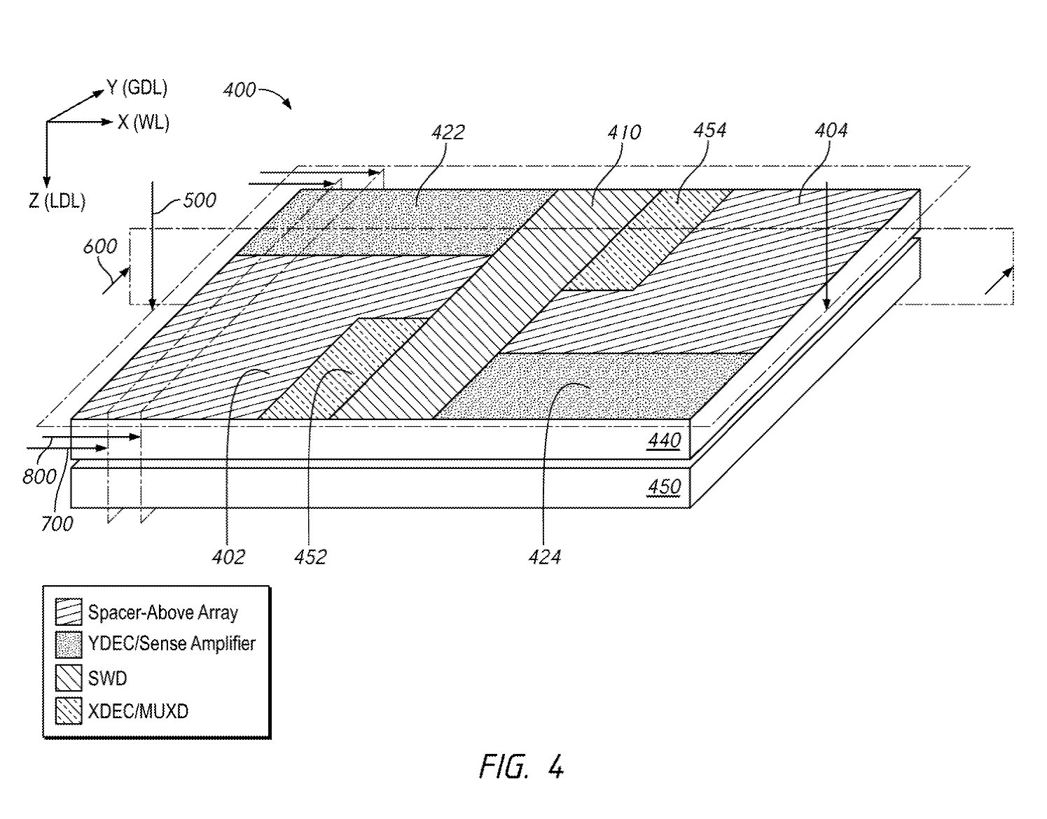

FIG. 4 is a perspective view of a memory quilt of a memory device according to some embodiments of the present disclosure. The memory quilt 400 may represent a portion of a memory device such as 100 of FIG. 1 and/or 200 of FIG. 2. The memory quilt 400 may include one or more memory arrays which have layouts similar to the memory array 300 of FIG. 3 in some embodiments. The memory quilt 400 may be generally similar to the quilt 202 of FIG. 2. However, FIG. 4 shows a perspective view rather than a ‘top down’ view of the xy plane.

The memory device which includes the quilt 400 includes a first die 440 (e.g., 212 of FIG. 2) and a second die 450 (e.g., 216 of FIG. 2). The first die 440 may includes the sense amplifiers, SWDs, and multiplexer drivers. For example the first die 440 may be a CMOS die. The second die 450 includes the memory array patches and staircase regions.

The memory quilt 400 includes a first memory patch 402 (e.g., 252 of FIG. 2), a second memory patch 406 (e.g., 254 of FIG. 2) and a SWD region 404 (e.g., 172 of FIG. 1, 272 of FIG. 2, and/or 306 of FIG. 3) in between. Each memory patch has an associated sense amplifier and column decoder region and an associated multiplexer driver and row decoder region. The patch 402 is associated with sense amplifier and column decoder region 422 (e.g., 174 and 164 of FIG. 1, 222 and 232 of FIG. 2, and/or 310 of FIG. 3) and multiplexer driver and row decoder region 452 (e.g., 176 and 162 of FIG. 1, 242 and 262 of FIG. 2, and/or 314 of FIG. 3). The patch 404 is associated with sense amplifier and column decoder region 424 (e.g., 174 and 164 of FIG. 1, 224 and 234 of FIG. 2, and/or 311 of FIG. 3) and multiplexer driver and row decoder region 454 (e.g., 176 and 162 of FIG. 1, 244 and 264 of FIG. 2, and/or 316 of FIG. 3).

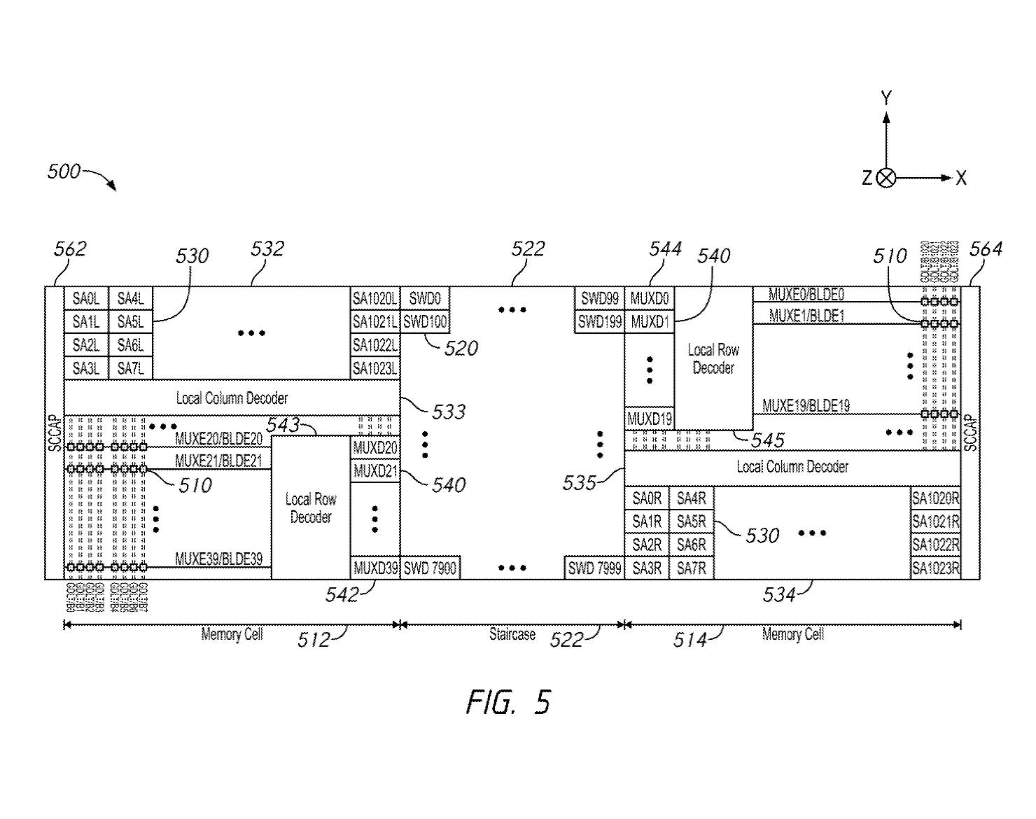

FIG. 4 shows planes 500, 600, 700, and 800 which represent the cross-sectional views of FIGS. 5, 6, 7 and 8, respectively. The plane 500 is a slice along an xy plane of the memory 400 shows the memory patches 402 and 404 as well as the sense amplifier/column decoder regions 422 and 424, the multiplexer driver/row decoder regions 452 and 454 and the SWD and staircase region 410.

The plane 600 is a slice along an xz plane of the memory which intersects a second memory patch 402, the SWD and staircase region 410 and a second memory patch 404. The plane 600 also intersects sense amplifier region 422. The plane 700 is a slice along a yz plane which intersects the first memory patch 402 and the sense amplifier region 422. The plane 800 is a similar yz slice to the plane 700 except that the plane 800 is slightly offset from the plane 700 in the x direction.

FIGS. 5-8 show different cross-sectional views of the memory device 400 of FIG. 4. Each of FIGS. 5-8 is illustrated with respect to an example embodiment where each memory patch such as 402 and 406 includes 8 Mbit of memory cells. Specifically, they are shown to include a grid of 80 word lines in the y direction and 100 word lines in the z direction, a grid of 80 LDLs in the y direction and 1024 LDLs in the x direction, and 1024 pairs of global digit lines side-by-side. This arrangement is shown as an illustrative example only. Other numbers and/or arrangements of word lines, global digit lines, local digit lines, memory cells, sense amplifiers, and so forth may be used in other example embodiments.

FIG. 5 is a top-down view of a memory quilt according to some embodiments of the present disclosure. The quilt 500 shows a view of an example quilt such as 202 of FIG. 2 and/or 400 of FIG. 4. The cross section 500 shows the plane 500 of FIG. 4. The quilt 500 represents a view along an example xy plane, showing a top layer of word lines extending horizontally in an x direction, global digit lines extending in a y direction, and local digit lines extending into the plane of the page in the z direction from the multiplexer circuits 510 where they intersect the GDL. The ‘top-down’ view of FIG. 5 shows a view of components which are not contained within a single plane. For example, the SWDs 520, sense amplifiers 530, multiplexer drivers 540, and the row decoders 543/545 and column decoders 533/535 may generally be located in a plane which is above the plane of the word lines, global digit lines, and multiplexers 510 in the z direction.

Certain components in the plane of the array, such as certain multiplexers 510, and portions of the global digit lines and word lines may be occluded by the sense amplifiers 530 and multiplexer drivers 540 which are above the memory patch. For example, the view of FIG. 5 shows global digit line pairs and multiplexer enable signal lines viewed through the spacer regions (e.g., 258 of FIG. 2) into the array patches (e.g., 252/254 of FIG. 2) below. The view of the components of the array patch visible in the view of FIG. 5 shows the multiplexer enable and bleed enable signal lines MUXE/BLDE and multiplexers 510 which run along a top of the array (in the z direction). The word lines may generally be stacked vertically below the MUXE/BLDE lines in the z direction, and the local digit lines and memory cells run below the multiplexers 510.

The quilt 500 shows two memory patches 512 and 514 (e.g., 252/254 of FIG. 2 and/or 404/404 of FIG. 4), a SWD/staircase region 522 (e.g., 172/182 of FIG. 1, 272/282 of FIG. 2, and/or 404 and 414 of FIG. 4), sense amplifier regions 532 and 534 (e.g., 174 of FIG. 1, 222/224 of FIG. 2, 310/311 of FIG. 3, and/or 422-424 of FIG. 4), multiplexer driver regions 542 and 544 (e.g., 176 of FIG. 1, 242 and 244 of FIG. 2, 314/316 of FIG. 3, and/or 452/454 of FIG. 4). Also shown in FIG. 5 are the local row decoders 543 and 545 (e.g., 162 of FIG. 1, and/or 262/264 of FIG. 2) and local column decoders (e.g., 164 of FIG. 1 and/or 232/234 of FIG. 2).

The SWD regions 522 includes SWD circuits 520. The sense amplifier regions 532 and 534 include sense amplifier circuits 530. The multiplexer driver regions 542 and 544 include multiplexer driver circuits 540. The array patches 512 and 514 each include a plurality of memory cells not shown in the view of FIG. 5 at the intersection of word lines and local digit lines. The ‘top’ of the local digit lines are selectively coupled through multiplexers 510 to one of the global digit lines of the associated global digit line pair. In the view of FIG. 5, the global digit line pairs are represented as a double line, one solid and one dotted, which are side-by-side in the xy plane. However, this is to help represent the paired nature of the GDLs. It does not necessarily represent the spatial arrangement of the GDL pair. For example, in some embodiments the two paired GDLs may be side by side in an xy plane, however in other embodiments the two paired GDLs may be above each other in a yz plane. Both GDLs of the pair are coupled to a same sense amplifier 530.

The sense amplifier circuits 530 in the sense amplifier regions 532 and 534 are coupled to both GDLs of a GDL pair. The GDL pair includes two GDLs labelled GDLT and GDLB. During an operation, the GDL of the GDL pair which is coupled to the active word line is used as a signal line and the other is used as a reference. For example, if the word line is coupled to GDLB, then the sense amplifier uses GDLT as a reference. Each patch includes 1024 GDL pairs, each coupled to one of 1024 sense amplifiers 530. In the example of FIG. 5, the sense amplifier regions 532 and 534 are arranged in grids with 4x256 sense amplifiers in the y and x directions respectively. For example, a first column includes SA0 coupled to GDLT0 and GDLB0, SA1 coupled to GDLT1 and GDLB1, SA2 coupled to GDLT2 and GDLB2, and SA3 coupled to GDLT3 and GDLB3. Vertical conductive elements (not shown in FIG. 5) extending in the z direction couple from the GDL pair up to the coupled sense amplifier.

The memory array includes 8000 word lines (not shown), WL0 to WL7999 . The word lines are arranged in 80 stacks of 100 word lines each. So the top row of word lines includes the visible word line (WL0) as well as 99 more word lines extending in the z direction into the plane from the point of view of the drawing. Multiplexer circuits 510 couple a ‘top’ of one or more LDLs to associated GDLs. The LDLs are arranged in a grid layout in an xy plane, with a row of the grid including 1024 LDLs along the x direction and a column of the grid including of 80 LDLs along the y direction. Each LDL is coupled through the multiplexer to one or other of the GDL pair. Which GDL of the GDL pair the LDLs are coupled to may change along the length of the GDL pair. The word lines WL extend from the first patch 512 to the second patch 514 under the SWD and staircase region 522.

The SWD and staircase region 522 includes a number of SWDs 520. There is a SWD for each word line. In this example there are 8000 SWDs 520, arranged in a grid of 80x100 SWDs in the yz plane. The SWDs 520 are arranged in 80 rows, with each row over a stack of WLs. Since the stacks of WLs are arranged with 100 WLs in each stack, each row of SWDs has 100 SWDs. Each SWD along a row has a conductive element running in the z direction down to the WL it is coupled to. The SWDs along a ‘row’ of the grid of SWDs are coupled to conductive elements of different lengths, since they are coupled to different depths (in the z direction) of word line. When activated by a row activation command, the SWD associated with the row address activates the associated word line.

The LDLs are coupled to the respective one of the GDL pair by a multiplexer circuit 510. The multiplexer circuit is generally positioned between a ‘top’ of the LDL in the z direction and the GDL. In the embodiment of FIG. 5, each multiplexer circuit 510 is associated with a pair of LDLs which are coupled in common through the multiplexer 510 to the associated one of the GDL pair. Other arrangements, such as a multiplexer for each LDL, a multiplexer for every 3 LDLs, etc., may be used in other example embodiments. A multiplexer driver circuit 540 is coupled by one or more signal lines extending in the x direction to a row of multiplexer driver circuits. The signal lines provide multiplexer enable signals MUXE, bleed enable signals BLDE or both. A row of multiplexers 510 may be coupled to a multiplexer driver in common.

In the embodiment of FIG. 5, the multiplexers 506 are arranged in an xy grid of 40 rows and 1024 columns. Each row of 1024 multiplexers is coupled in common to a multiplexer driver 540 in an associated one of the multiplexer driver regions 542-548. Accordingly, there are 40 multiplexer drivers 540 in each region 542 and 544. Each region 542-548 is associated with both of the regions 512 and 514. The region 542 is above the patch 512 and the region 544 is above the patch 514/

The multiplexer regions 542-548 each include multiplexer drivers 540 arranged in a column extending in y direction. Each multiplexer driver 540 may be associated with a row of multiplexers 510 extending in the x direction in the associated patch 512-518. In other words, each multiplexer driver 540 may be associated with one or more ‘stack’ of word. So, for example a first multiplexer driver MUXD0 may be associated with WL0 to WL199 since in the embodiment of FIG. 5 each multiplexer driver is associated with two stacks of word lines.

FIG. 5 also shows a pair of SCCAP regions 562 and 564 (e.g., 110 of FIG. 1) which are positioned on the edges of the memory quilt 500. The two SCCAP regions 562 and 564 are positioned on opposite edges of the memory quilt 500 in the x direction.

In an example operation, when a row activation command is received along with a row address, the SWD 520 associated with that address activates the associated word line. The associated multiplexer driver 540 activates the multiplexer circuit 510 so that the LDLs which intersect the active word line are coupled to the respective one of the pair of associated GDLs. When the word line is activated, the memory cells along that word line are coupled to the intersecting LDL and change a voltage of the LDL and the GDL that LDL is coupled to based on the stored charge. The SA coupled to that GDL senses this change by comparing the voltage on the GDL of the pair which is coupled to the word line to a pre-charge voltage on the other GDL of the pair and amplifies the difference during a read operation, or drives a new value onto the GDL pair in a write operation.

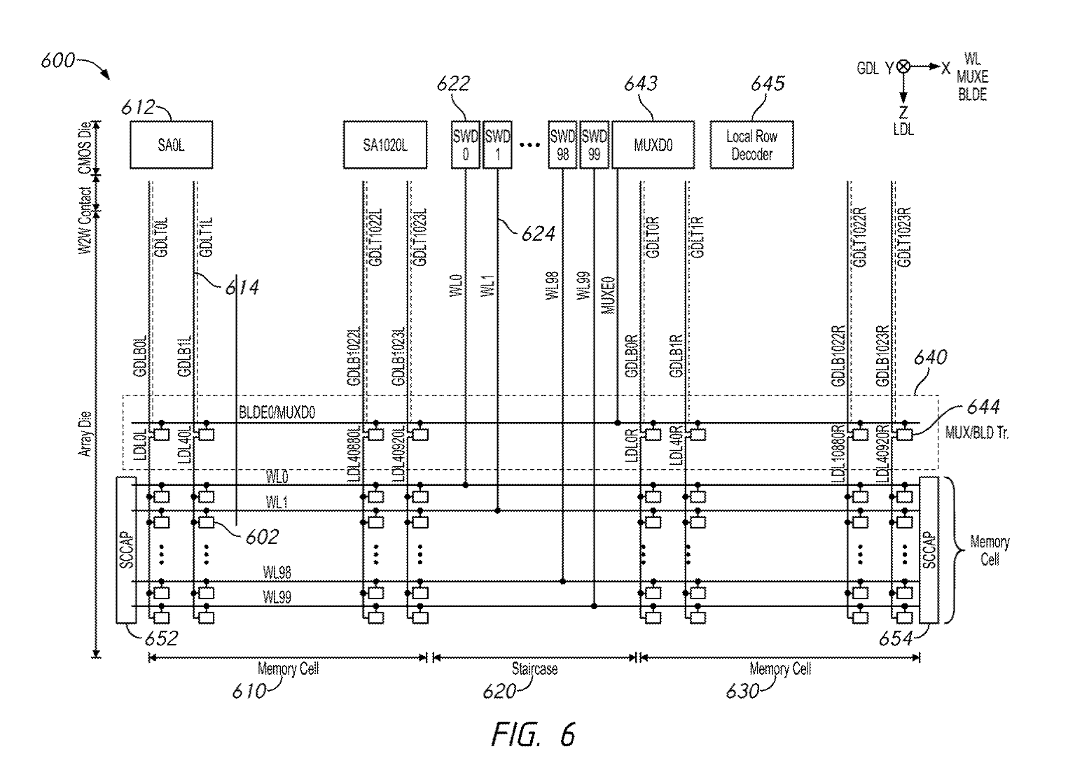

FIG. 6 is a cross sectional view of a memory device according to some embodiments of the present disclosure. The cross section 600 shows the plane 600 of FIG. 4. The cross section 600 represents a view along an example xz plane, showing word lines running horizontally along the x direction, local digit lines running vertically along a z direction, and global digit line pairs running into and out of the plane of the page along a y direction. Pairs of vertical conductive elements 614 are shown which runs ‘behind’ the plane of the cross section 600. The vertical conductive elements 614 are coupled to the sense amplifiers 612, which are positioned over the memory cells. The sense amplifiers 612 shown are in the sense amplifier portions which are positioned over the first memory patch 610 (e.g., sense amplifier regions 222 of FIG. 2, 310 of FIG. 3, 422 of FIG. 4, and/or 532 of FIG. 5). Each sense amplifier 612 represents a ‘front’ sense amplifier in a column of sense amplifiers that extends out of the plane of the page.

The cross section 600 shows a first memory patch 610 (e.g., 252 of FIG. 2, 402 of FIG. 4, and/or 512 of FIG. 5), a staircase region 620 (e.g., 286 of FIG. 2, 410 of FIG. 4, and/or 522 of FIG. 5), and a second memory patch 630 (e.g., 254 of FIG. 2, 404 of FIG. 4, and/or 514 of FIG. 5). The cross section 600 shows a row a SWDs 622 associated with the WLs running through the patches 610 and 630, a multiplexer driver 643 (e.g., 176 of FIG. 1, 244 of FIG. 2, 316 of FIG. 3, 454 of FIG. 4, and/or 544 of FIG. 5) and local row decoder 645 (e.g., 162 of FIG. 1, 264 of FIG. 2, and/or 545 of FIG. 5).

Each word line is coupled to a respective SWD 622. For example, the cross section 600 shows SWD0 to SWD99, which are associated with WL0 to WL99 respectively. The SWDs 622 are located above in the z direction a staircase region 620 which is between the two patches 610 and 630 in the x direction. Each SWD 622 is coupled to a vertical conductive element 624 which extends in the z direction to the associated word line. Along a row of SWDs 622 like the one shown in FIG. 6, each of these vertical conductive elements 624 may be a different length, since the WLs are at different depths in the z direction. In the example layout of FIG. 6, the shortest vertical conductive element, coupled to the ‘top’ word line WL0, is on the far left, while the longest vertical conductive element, coupled to the ‘bottom’ word line WL99, is on the far right. Other arrangements may be used in other example embodiments.

The cross section 600 shows a ‘stack’ of word lines. In this case the word lines WL0 to WL99. A number of LDLs extend vertically in the z direction and memory cells 602 are coupled at the intersection of the LDLs and the WLs. In the example implementation, there are 81,920 LDLs per patch from LDL0 to LDL81919. Each LDL seen in the cross section 600 represents a ‘top’ of a stack of 80 LDLs which extend in the y direction. Thus the leftmost LDL in the patch 610 is LDL0L, the next LDL is LDL80L, the next is LDL160L and so forth up to LDL81840L. Similarly, the LDLs in the patch 620 are LDL0R up to LDL81919R.

The view of FIG. 6 includes digit line multiplexers 644 (e.g., 184 of FIG. 1, 318 of FIG. 3, and/or 510 of FIG. 5) in a digit line multiplexer region 640, and example multiplexer drivers 643. The multiplexers 644 selectively couple a set of LDLs to one of the GDLs of the respective GDLs. The multiplexer driver 643 is coupled to one or more signal lines extending the X direction which carry the multiplexer enable signal MUXE and the bleed enable signal BLDE which control the multiplexer region 640. For example, a first signal line couples the multiplexers 644 to MUXE and a second signal line couples the multiplexers 644 to BLDE. The multiplexer driver 643 represents a single driver in a multiplexer region. In particular, in the view 600 of FIG. 6, the driver is MUXD0, which provides signals MUXE0 and BLDE0. Additional drivers are stacked through the plane of the page in the y direction.

Responsive to a row activation command and a row address, local row decoder 645 selects a SWD 622 and multiplexer driver 643 based on the row address. For example, if the row address is associated with WL1, then MUXD0 will provide MUXE0, and the SWD1622 will provide an enable signal WL1. The selected multiplexer driver activates a set of multiplexers 640 to couple the LDLs to one of the pair of GDLs. The selected SWD 622 activates the associated word line. This couples the memory cells 602 in the two patches 610 and 630 to be coupled to the LDLs which intersect that word line. The memory cells along the activated WL drive a voltage onto the intersecting LDLs, which then drive a voltage to the coupled GDL of the pair of GDLs through the activated multiplexers 644. The other LDLs, which are stacked in the Y direction and not visible in FIG. 6, are coupled to multiplexers which are coupled to different multiplexer drivers, and thus are not coupled to the GDLs. This may help reduce the capacitance of the GDL since each GDL is only coupled to the selected LDLs during a given operation a time.

In some embodiments, the SWDs 622 and multiplexer drivers 642 may be located in a CMOS die (e.g., 212 of FIG. 2B) while the memory cells, LDLs, WLs, and, if used multiplexer region 640 are located in an array die (e.g., 216 of FIG. 2B). The vertical elements 624, as well as the vertical portions of the GDLs may extend from the array die to the CMOS die and may include contacts between the two dice not shown in FIG. 6.

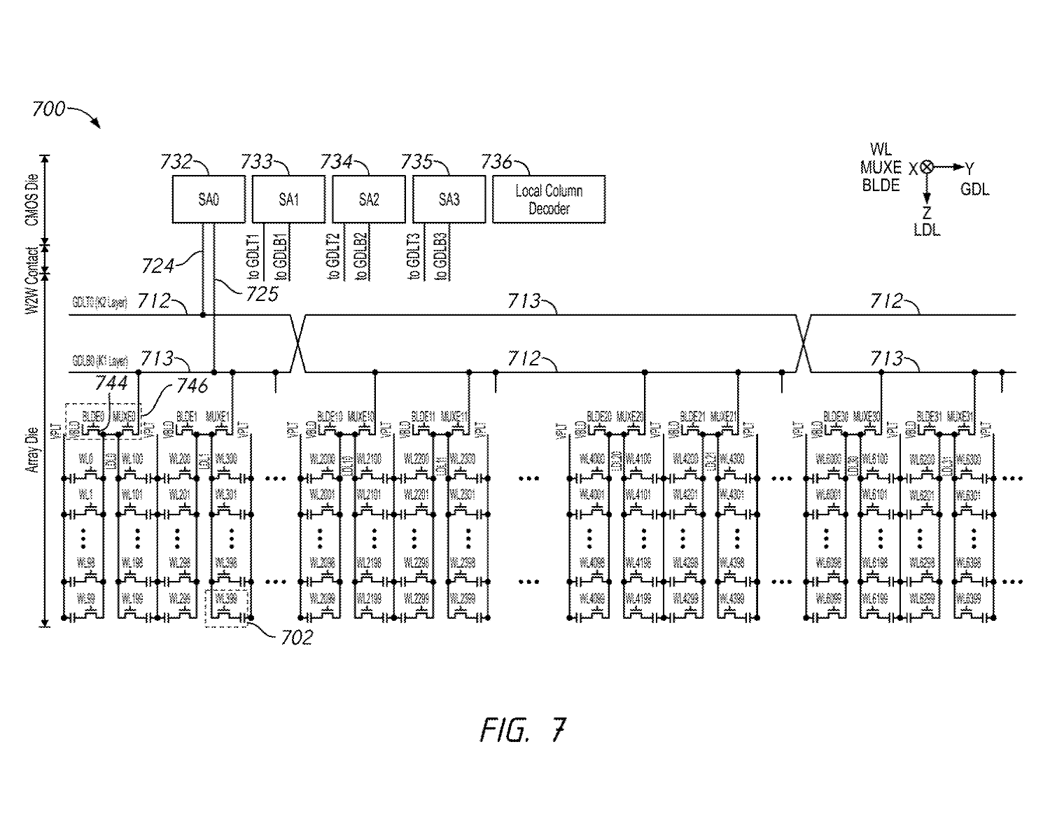

FIG. 7 is a cross sectional view of a memory device according to some embodiments of the present disclosure. The cross section 700 shows the plane 700 of FIG. 7. The cross section 700 represents a view along an example yz plane, showing a pair of global digit lines 712 and 713 running horizontally in the y direction, local digit lines running vertically in the z direction, and word lines running through the plane of the page in the x direction. The cross section 700 shows a portion of a first memory patch 710 (e.g., 252 of FIG. 2, 402 of FIG. 4, 512 of FIG. 5, and/or 610 of FIG. 6).

The cross section 700 intersects 8000 word lines in the memory patch. The word lines are organized in a grid in the yz plane with eighty columns in the z direction that have 100 word lines each. The 8000 word lines in the patch are organized in a grid of 80 memory cells in the x direction and 100 memory cells in the z direction. Each column of memory cells 702 is coupled to a local digit line, here labelled LDL0 to LDL79. In the embodiment of FIG. 7, the LDLs are paired and each pair LDLs is coupled in common to a multiplexer circuit 742. In some embodiments, each LDL may couple separately through a multiplexer to the GDL, rather than being paired.

Each memory cell 702 includes a capacitive element and a transistor. The gate of the transistor is coupled to the word line. One side of the capacitive element is coupled to a plate voltage VPLT, and the other side is coupled through the transistor to the LDL. When the word line is activated, the SWD drives a voltage along the word line which activates the transistor, coupling the capacitive element to the LDL.

The cross section 700 shows sense amplifiers 732, 733, 734, and 735. The sense amplifiers are part of a column of sense amplifiers in the y direction in a sense amplifier region. Each sense amplifier 732-735 is coupled to a different GDL pair. For example, the sense amplifier SA0 is coupled to GDLT0712 and GDLB0 713, which form a sense amplifier pair. During an example operation, one of the two GDLs 712/713 is used to carry information, and the other is used as a reference. Along the length of the two GDLs, different LDLs are coupled to either the first or the second GDL of the pair. For example, as shown in FIG. 7, LDL0 to LDL9 may be coupled to GDLB0713, LDL10 to LDL29 may be coupled to GDLT0 712, LDL30 to LDL49 may be coupled to GDLT0 712, and so forth.

In some example embodiments, such as the one shown in FIG. 7, the two GDLs in the pair may be stacked in the z direction, with one GDL over the top of the other. For example one GDL of the pair may be in one metal layer, and the other GDL may be in a second metal layer. In some embodiments, the GDLs of the pair may ‘twist’ or switch which GDL of the pair is in which metal layer. For example, in the embodiment of FIG. 7, GDLT0 is above GDLB0 when the pair runs above LDL0 to LDL9, but then the GDLs twist and GDLB0 is above GDLT0 from LDL10 to LDL19. This may be useful to allow the LDLs to always couple to the lower of the two GDLs (e.g., the GDL closer to the LDLs), but allow for changes in which LDLs are coupled to which of the GDL pair along its length. In this manner, portions of both of the GDLs 712 and 713 are in both metal layers.

The sense amplifiers 732-735 are shown positioned above at least some of the memory cells 702. Vertical conductive elements 724 and 725 couple the GDLs of the pair GDLB0 713 and GDLT0 712 up from the array die to the CMOS die. Since the vertical conductive elements are also over the array and the memory cells 702, the vertical conductive elements may run directly up from the array die to the sense amplifiers, without the need for additional horizontal (e.g., in the xy plane) routing. The vertical conductive elements 724 and 725 may have different lengths (e.g., analogous to the staircase region) since they run to different ‘depths’ along the z direction. FIG. 7 also shows a local column decoder 736 (e.g., 164 of FIG. 1, 232 of FIG. 2, and/or 533 of FIG. 5) which determines which GDL pair is coupled to the global input/output lines during an operation.

Each multiplexer circuit 742 includes a multiplexer transistor 746 and a bleed transistor 744. The bleed transistor 744 has a gate coupled to a bleed enable signal BLDE provided by a multiplexer driver and terminals coupled between a ground voltage VBLD and the pair of local digit lines. The multiplexer transistor 746 has a gate coupled to a multiplexer enable signal MUXE and terminals coupled between one of the GDLs and the pair of LDLs.

During an example operation, if a row address is received associated with the first patch 710, then the multiplexer driver which controls the LDL which intersects the WL activates the multiplexer transistor 746 by providing MUXE, and each of the other multiplexer drivers provide BLDE to their respective bleed transistor 744 to couple those LDLs to VBLD and prevent them from floating. For example, if the row address indicates WL 101, which intersects LDL0, then MUXD0 provides MUXE0, which couples LDL0 to GDLB0 713. The other LDLs receive BLDE at an active level, (e.g., BLDE1 to BLDE39) which couples those LDLs to VBLD instead of to the respective GDL.

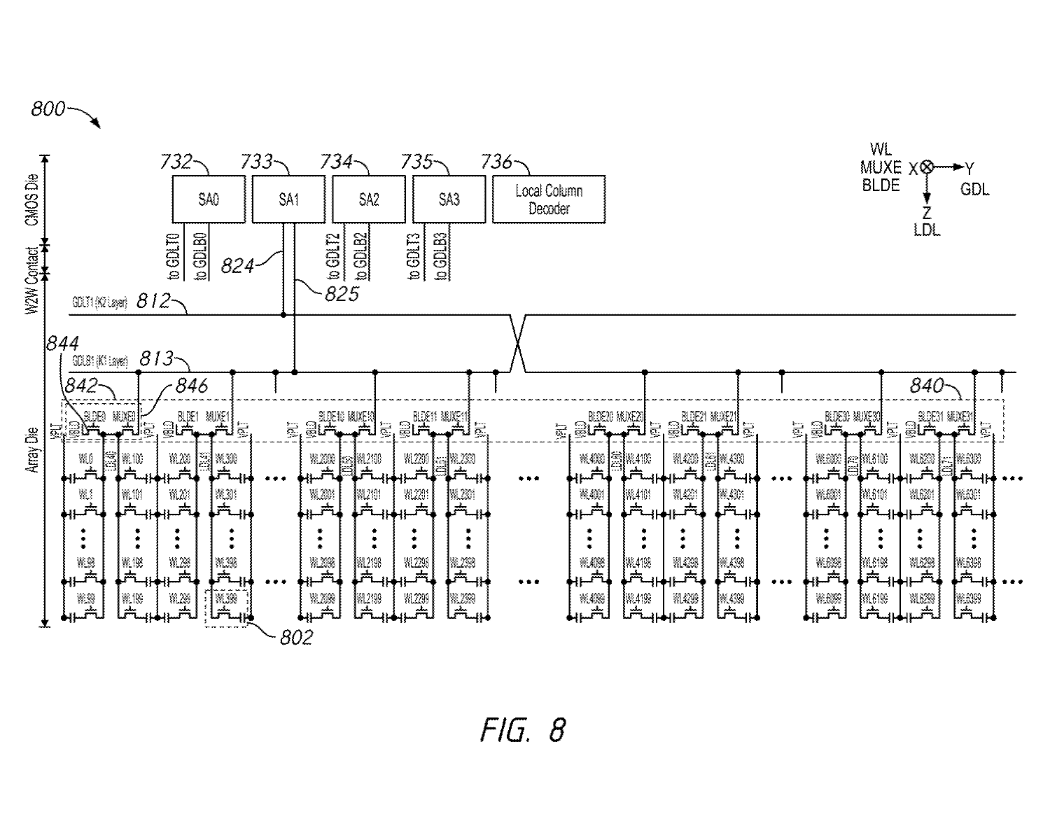

FIG. 8 is a cross sectional view of a memory device according to some embodiments of the present disclosure. The cross section 800 is generally similar to the cross section 700 of FIG. 7, except that the cross section 800 is offset from the cross section 700 in the +x direction and includes the adjacent pair of GDLs GDLT1812 and GDLB1813. For the sake of brevity certain details which were already previously described with respect to FIG. 7 are not repeated again with respect to FIG. 8. FIG. 8 uses similar reference numbers for similar components, and reuses the same reference numbers as FIG. 7 for components which extend through the x direction to be visible in both cross sections 700 and 800.

In the cross-section 800 of FIG. 8, a different GDL pair is shown. The GDL pair GDLT1812 and GDLB1813 are coupled along vertical elements 824 and 825 (respectively) to SA1733. Also, the GDL pair of GDLT/B1 twists in different places than the GDL pair of GDLT/B0 of FIG. 7. For example, the GDL pair GDLT1 812 and GDLB1 813 twist between LDL59 and LDL60 instead of between LDL9 and LDL10.

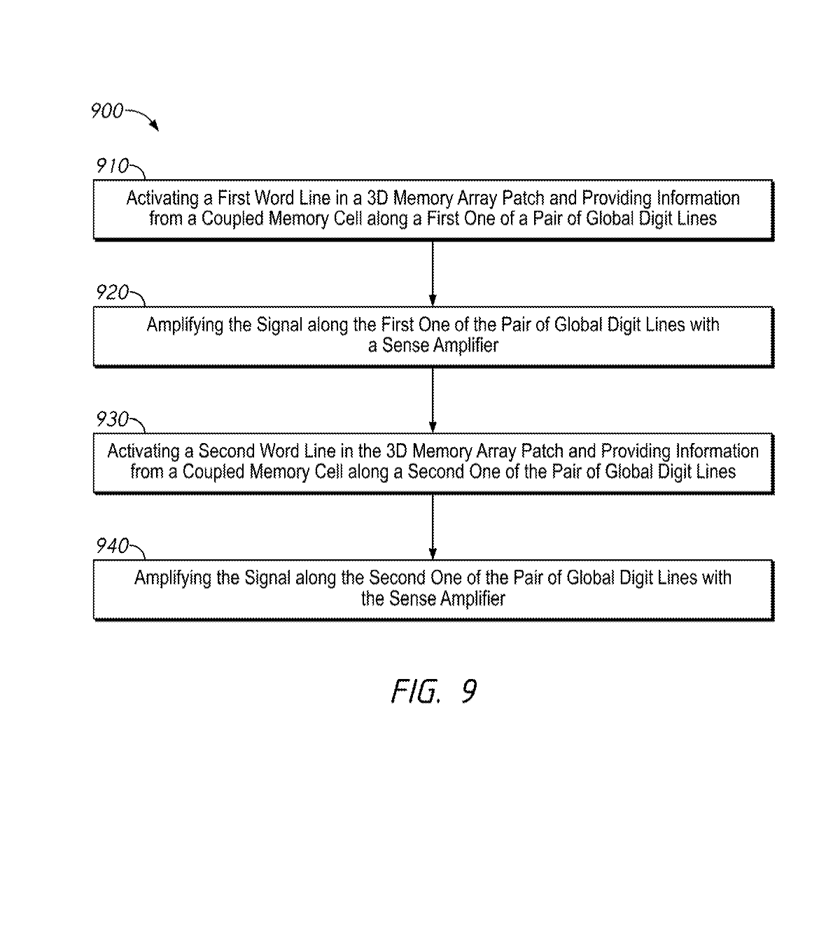

FIG. 9 is a flow chart of a method of operating a 3D memory device according to some embodiments of the present disclosure. The method 900 may, in some embodiments, be performed by one or more of the apparatuses or systems described herein. For example, the method 900 may be performed by one or more of the 3D memory device 100 of FIG. 1, the memory dice 200 of FIG. 2, the memory array 300 of FIG. 3, the memory quilt 400 of FIG. 4, and/or the components in the cross-sectional views 500, 600, 700, and/or 800 of FIGS. 5-8.

The method 900 generally begins with box 910, which describes activating a first word line in a 3D memory array patch and providing information from a coupled memory cell along a first one of a pair of global digit lines. For example, the method 900 may include selecting a sub word line driver (e.g., 172 of FIG. 1, 520 of FIG. 5 and/or 622 of FIG. 6) with a local row decoder (e.g., 162 of FIG. 1, 262/264 of FIG. 2, 543/545 of FIG. 5, and/or 645 of FIG. 6) responsive to a row activation command and a row address. The method 900 may include activating the first word line with the selected sub-word line driver. Which of the pair of global digit lines (e.g., GDLT and GDLB) receives the information may be determined by which local digit line the word line intersects.

Box 910 is generally followed by box 920 which describes amplifying the signal along the first one of the pair of global digit lines with a sense amplifier. For example, the method 900 may include comparing the signal along the first one of the pair of global digit lines to a reference along the second one of the pair of global digit lines with the sense amplifier (e.g., 174 of FIG. 1, 530 of FIG. 5, 612 of FIG. 6, and/or 732-735 of FIGS. 7-8).

Box 920 may generally be followed by box 930, which describes activating a second word line in the 3D memory array patch and providing information from a coupled memory cell along a second one of the pair of global digit lines. The method 900 may include receiving a row activation command and a second row address, and selecting a second sub-word line driver with the local row decoder based on the second row address.

Box 930 may generally be followed by box 940, which describes amplifying the signal along the second one of the pair of global digit lines with the sense amplifier. For example, the method 900 may include comparing the comparing the signal along the second one of the pair of global digit lines to a reference along the first one of the pair of global digit lines with the sense amplifier. The two global digit lines may generally extend in a same direction away from the sense amplifier (e.g., both run in a +y direction or both run in the -y direction). In some embodiments, the pair of global digit lines may run underneath the sense amplifier and pair of vertical conductive elements may couple the pair of global digit lines up to the sense amplifier. In some embodiments, the sense amplifier may be in a sense amplifier region positioned above an edge of the 3D memory array patch.

In some embodiments 900, the method may include selectively coupling a first local digit line which intersects the first word line to the first one of the pair of global digit lines and selectively coupling a second local digit line which intersects the second word line to the second one of the pair of global digit lines.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a word line extending in a first direction;
a local digit line extending in a second direction orthogonal to the first direction;
a memory cell located at the intersection of the word line and the local digit line;
a sense amplifier; and
a pair of global digit lines coupled to the sense amplifier, wherein the pair of global digit lines is arranged on one side of the sense amplifier, wherein the pair of global digit lines extends in a third direction orthogonal to the first and the second direction and wherein one of the pair of global digit lines is coupled to the local digit line.

2. The apparatus of claim 1, wherein the pair of global digit lines includes a first global digit line in a first metal layer and a second global digit line in a second metal layer.

3. The apparatus of claim 1, wherein one of the pair of global digit lines is above the other of the pair of global digit lines in the second direction.

4. The apparatus of claim 3, wherein a first portion of a first global digit line of the pair of global digit lines is above a first portion of the second global digit line of the pair of global digit lines and a second portion of the first global digit line is below a second portion of the second global digit line.

5. The apparatus of claim 1, wherein the sense amplifier is located above at least one of the first and the second memory cells in the second direction.

6. The apparatus of claim 5, further comprising:
a first vertical conductive element coupling one of the pair of global digit lines to the sense amplifier; and
a second vertical conductive element coupling another of the pair of global digit lines to the sense amplifier,
wherein the first vertical conductive element ad the second vertical conductive element extend in the second direction.

7. The apparatus of claim 1, wherein the sense amplifier is in a different die than the word line, local digit line, memory cell, and the pair of global digit lines.

8. The apparatus of claim 1, further comprising:
a second word line extending in the first direction;
a second local digit line extending in the second direction; and
a second memory cell located at the intersection of the second word line and the second local digit line, wherein the second local digit line is coupled to a different one of the pair of global digit lines than the local digit line.

9. The apparatus of claim 1, further comprising a multiplexer configured to selectively couple the local digit line to the one of the pair of global digit lines.

10. An apparatus comprising:
a 3D memory array patch comprising a plurality of memory cells arranged in a 3D array, the plurality of memory cells disposed at the intersection of a plurality of word lines with a plurality of local digit lines, wherein sets of the local digit lines are coupled to a respective pair of global digit lines of a plurality of pairs of global digit lines;
a plurality of sense amplifiers, each coupled to one of the plurality of pairs of global digit lines, wherein the plurality of sense amplifiers are positioned above at least a portion the 3D memory array patch, wherein the coupled one of the plurality of pairs of global digit lines are both arranged on one side of a coupled one of the plurality of sense amplifiers.

11. The apparatus of claim 10, wherein a first portion of the local digit lines of the set of local digit lines are coupled to a first global digit line of the respective pair of global digit lines and wherein a second portion of the local digit lines of the set of local digit lines are coupled to a second global digit line of the respective pair of global digit lines.

12. The apparatus of claim 10, further comprising:
a first metal layer; and
a second metal layer,
wherein each of the plurality of pairs of global digit lines has a first global digit line and a second global digit line, and wherein each of the first and the second global digit lines have portions in the first metal layer and portions in the second metal layer.

13. The apparatus of claim 10, further comprising a plurality of multiplexer circuits each configured to selectively couple ones of the plurality of local digit lines to one of the global digit lines of the respective pair of global digit lines.

14. The apparatus of claim 10, wherein the plurality of sense amplifiers are in a different die than the 3D memory array patch.

15. The apparatus of claim 10, wherein the plurality of word lines extend in a first direction, wherein the plurality of local digit lines extend in a second direction, and wherein the plurality of pairs of global digit lines extend in a third direction.

16. An apparatus comprising:
a plurality of word lines extending in a first direction;
a first plurality of local digit lines extending in a second direction orthogonal to the first direction;
a first plurality of memory cells disposed at the intersection of the plurality of word lines and the first plurality of local digit lines;
a first plurality of pairs of global digit lines extending in a third direction orthogonal to the first and the second direction, wherein sets of the first plurality of local digit lines are coupled to a respective pair of the first plurality of pairs of global digit lines;
a first plurality of sense amplifiers each coupled to a pair of global digit lines of the first plurality of pairs of global digit lines wherein the first plurality of pairs of global digit lines are arranged on one side of the first plurality of sense amplifiers;
a second plurality of local digit lines extending in the second direction;
a second plurality of memory cells disposed at the intersection of the plurality of word lines and the second plurality of local digit lines;
a second plurality of pairs of global digit lines extending in the third direction, wherein sets of the second plurality of local digit lines are coupled to a respective pair of the second plurality of pairs of global digit lines; and
a second plurality of sense amplifiers each coupled to a pair of global digit lines of the second plurality of pairs of global digit lines wherein the second plurality of pairs of global digit lines are arranged on one side of the second plurality of sense amplifiers.

17. The apparatus of claim 16, further comprising a plurality of sub-word line drivers each coupled to a respective one of the plurality of word lines, wherein the plurality of sub-word line drivers are between the first and the second plurality of memory cells along the first direction.

18. The apparatus of claim 16, wherein the first plurality of sense amplifiers are above at least a portion of the first plurality of memory cells, and
wherein the second plurality of sense amplifiers are above at least a portion of the second plurality of memory cells.

19. The apparatus of claim 16, further comprising:
a first plurality of multiplexers configured to selectively couple the first plurality of local digit lines to the first plurality of pairs of global digit lines; and
a second plurality of multiplexers configured to selectively couple the second plurality of local digit lines to the second plurality of pairs of global digit lines.

20. The apparatus of claim 16, further comprising a first metal layer and a second metal layer; wherein each of the global digit lines of the first plurality of pairs global digit lines and each of the global digit lines of the global digit lines of the second plurality of pairs of global digit lines have portions in both the first metal layer and the second metal layer.
